(19) United States
(12) Patent Application Publication
(10) Pub. No.: US 2024/0329487 A1
(43) Pub. Date: Oct. 3, 2024

(54) SHAPABLE DISPLAY DEVICE

(71) Applicant: E Ink Holdings Inc., Hsinchu (TW)

(72) Inventors: Ming-Huan Yang, Hsinchu (TW); Chen Chu Tsai, Hsinchu (TW); Chao Feng Sung, Hsinchu (TW); Deng-Kuen Shiau, Hsinchu (TW); Yue-Feng Lin, Hsinchu (TW); Chih-Chia Chen, Hsinchu (TW)

(73) Assignee: E Ink Holdings Inc., Hsinchu (TW)

(21) Appl. No.: 18/603,217

(22) Filed: Mar. 13, 2024

Related U.S. Application Data
(60) Provisional application No. 63/453,168, filed on Mar. 20, 2023.

(51) Int. Cl. G02F 1/1676; G02F 1/167; G02F 1/16755

(52) U.S. Cl. CPC G02F 1/1676; G02F 1/167; G02F 1/16755

(57) ABSTRACT

A shapable display device includes a first deformable substrate, a first stretchable electrode layer, a stretchable display medium layer, and a second stretchable electrode layer. The first stretchable electrode layer is disposed on the first deformable substrate. The stretchable display medium layer is disposed on the first stretchable electrode layer. The second stretchable electrode layer is disposed on the stretchable display medium layer. The stretchable display medium layer is between the first stretchable electrode layer and the second stretchable electrode layer.

### CROSS-REFERENCE TO RELATED APPLICATION

This application claims the priority benefit of U.S. Provisional application Ser. No. 63/453,168, filed on Mar. 20, 2023. The entirety of the above-mentioned patent application is hereby incorporated by reference herein and made a part of this specification.

### BACKGROUND

### Technical Field

The disclosure relates to a display device, and particularly relates to a shapable display device.

### Description of Related Art

With the advancement of technology, various display media are widely used in various display applications, such as televisions, laptops, e-paper books, mobile phones, various electronic labels and in mold electronics (IME) technology applications for large advertising billboards and stores, etc.

Among them, an electrophoretic display medium, for example, is used in color-changing electronic paper, and can make color gradient changes or flashes between two colors or a plurality of colors and be freely cut into any shape. The electrophoretic display medium is a special dynamic design material. If such a color-changing electronic paper can be further three-dimensionally shaped into surfaces of different shapes, it can also make the originally static building walls and art works flow and dynamically display colors or patterns. Therefore, the color-changing electronic paper that can be three-dimensionally shaped is an important development trend.

### SUMMARY

The disclosure provides a shapable display device, which can achieve a three-dimensional shaping effect.

An embodiment of the disclosure provides a shapable display device, including a first deformable substrate, a first stretchable electrode layer, a stretchable display medium layer, and a second stretchable electrode layer. The first stretchable electrode layer is disposed on the first deformable substrate, and the stretchable display medium layer is disposed on the first stretchable electrode layer. The second stretchable electrode layer is configured on the stretchable display medium layer. The stretchable display medium layer is between the first stretchable electrode layer and the second stretchable electrode layer.

In the shapable display device according to the embodiment of the disclosure, since the first deformable substrate, the first stretchable electrode layer, the stretchable display medium layer, and the second stretchable electrode layer are all deformable or stretchable, the display device can be configured on an object with a three-dimensional shape and bend along with the three-dimensional shape. In other words, the shapable display device of the embodiment of the disclosure can achieve a three-dimensional shaping effect.

### BRIEF DESCRIPTION OF THE DRAWINGS

FIG. 1 is a schematic cross-sectional view of a shapable display device before and after shaping according to an embodiment of the disclosure.

FIG. 2 is a schematic cross-sectional view of a shapable display device before and after shaping according to another embodiment of the disclosure.

FIG. 3 is a schematic cross-sectional view of a shapable display device before and after shaping according to yet another embodiment of the disclosure.

FIG. 4 is a schematic cross-sectional view of a shapable display device before and after shaping according to still another embodiment of the disclosure.

FIG. 5 is a schematic cross-sectional view of a shapable display device before and after shaping according to another embodiment of the disclosure.

FIG. 6 is a schematic cross-sectional view of a shapable display device before and after shaping according to yet another embodiment of the disclosure.

FIG. 7 is a schematic cross-sectional view of a shapable display device before and after shaping according to still another embodiment of the disclosure.

FIG. 8 is a schematic cross-sectional view of a shapable display device before and after shaping according to another embodiment of the disclosure.

FIG. 9 is a schematic cross-sectional view of a shapable display device before and after shaping according to yet another embodiment of the disclosure.

FIG. 10 is a schematic top view of a shapable display device formed by designing the shapable display device of FIG. 6 using segment code technology.

### DESCRIPTION OF THE EMBODIMENTS

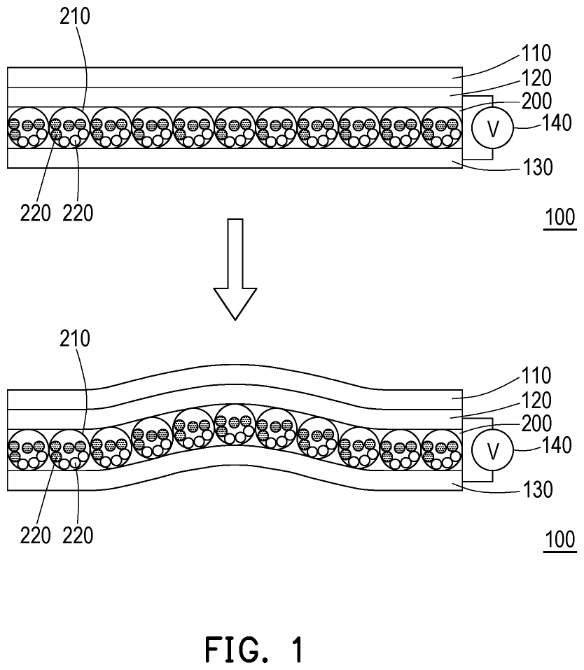

FIG. 1 is a schematic cross-sectional view of a shapable display device before and after shaping according to an embodiment of the disclosure. Referring to FIG. 1, a shapable display device 100 of the embodiment includes a first deformable substrate 110, a first stretchable electrode layer 120, a stretchable display medium layer 200, and a second stretchable electrode layer 130. The first stretchable electrode layer 120 is disposed on the first deformable substrate 110. The stretchable display medium layer 200 is disposed on the first stretchable electrode layer 120. The second stretchable electrode layer 130 is disposed on the stretchable display medium layer 200. The stretchable display medium layer 200 is between the first stretchable electrode layer 120 and the second stretchable electrode layer 130.

In the embodiment, the stretchable display medium layer 200 is, for example, a stretchable electrophoretic display medium layer, and the shapable display device 100 is, for example, a shapable electrophoretic display device. Specifically, in the embodiment, the stretchable display medium layer 200 includes a plurality of capsule structures 210 and a plurality of electrophoretic particles 220. The capsule structures 210 are distributed in the stretchable display medium layer 200, and the electrophoretic particles 220 are configured in the capsule structures 210. In the embodiment, by applying a voltage between the first stretchable electrode layer 120 and the second stretchable electrode layer 130 through a voltage source 140, it may enable the electrophoretic particles 220 to move in the capsule structures 210 to form different grayscales, thereby allowing the stretchable display medium layer 200 to display different image pictures. In an embodiment, the electrophoretic particles 220 may include colored electrophoretic particles, such as red electrophoretic particles, green electrophoretic particles, and blue electrophoretic particles in a plurality of different capsule structures 210 respectively. However, in another embodiment, the electrophoretic particles 220 may also include black electrophoretic particles and white electrophoretic particles. In other embodiments, the stretchable display medium layer 200 may also be a stretchable electrowetting display medium layer, an organic light-emitting diode display medium layer, or a liquid crystal display medium layer, but the disclosure is not limited thereto.

In the shapable display device 100 of the embodiment, since the first deformable substrate 110, the first stretchable electrode layer 120, the stretchable display medium layer 200, and the second stretchable electrode layer 130 are all deformable or stretchable, the display device 100 can be configured on an object with a three-dimensional shape and bend along with the three-dimensional shape. In other words, the shapable display device 100 of the embodiment can achieve a three-dimensional shaping effect. For example, the upper figure of FIG. 1 illustrates the shapable display device 100 before shaping, whereas the lower figure of FIG. 1 illustrates the shapable display device 100 after shaping, in which the above-mentioned object with a three-dimensional shape may be disposed below, and the second stretchable electrode layer 130 is configured on the object with a three-dimensional shape.

In an embodiment, the first deformable substrate 110 is a thermoplastic substrate, that is, the first deformable substrate 110 is deformable when heated, but is non-deformable after cooling to room temperature. Therefore, the shape of the shapable display device 100 shown in the upper figure of FIG. 1 can be changed into the shape of the shapable display device 100 shown in the lower figure of FIG. 1 through thermoforming, so as to conform to the surface shape of the object with a three-dimensional shape configured below. Then, after cooling to room temperature, the shapable display device 100 forms a fixed shape as shown in the lower figure of FIG. 1. However, in other embodiments, the first deformable substrate 110 may also be deformable at normal temperature.

In an embodiment, the material of the first deformable substrate 110 is, for example, amorphous polyethylene terephthalate (APET), and the materials of the first stretchable electrode layer 120 and the second stretchable electrode layer 130 are, for example, poly(3,4-ethylenedioxythiophene) (PEDOT).

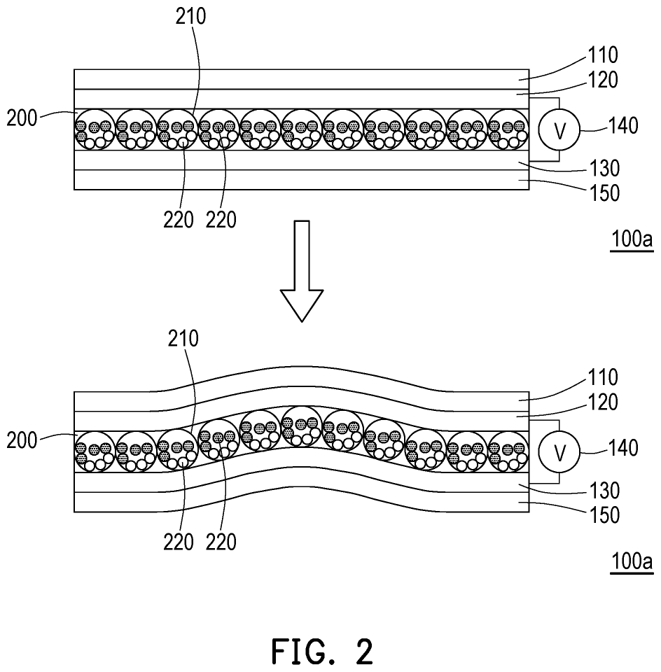

FIG. 2 is a schematic cross-sectional view of a shapable display device before and after shaping according to another embodiment of the disclosure. Referring to FIG. 2, a shapable display device 100a of the embodiment is similar to the shapable display device 100 of FIG. 1, and the main differences between the two are as follows. The shapable display device 100a of the embodiment further includes a second deformable substrate 150 configured on the second stretchable electrode layer 130. The second stretchable electrode layer 130 is located between the stretchable display medium layer 200 and the second deformable substrate 150. In an embodiment, the second deformable substrate 150 may be a thermoplastic substrate. However, in other embodiments, the second deformable substrate 150 may also be a substrate deformable at normal temperature. In an embodiment, the material of the second deformable substrate 150 is amorphous polyethylene terephthalate (APET).

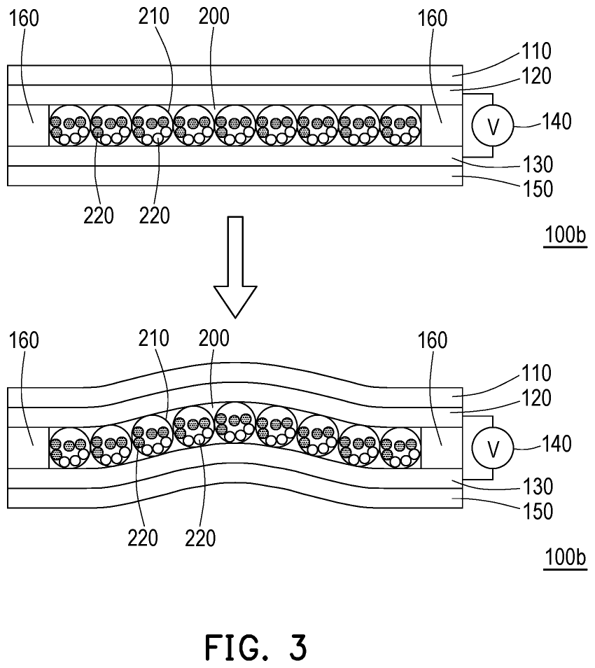

FIG. 3 is a schematic cross-sectional view of a shapable display device before and after shaping according to yet another embodiment of the disclosure. Referring to FIG. 3, a shapable display device 100b of the embodiment is similar to the shapable display device 100a of FIG. 2, and the main differences between the two are as follows. The shapable display device 100b of the embodiment further includes a package material 160 configured around the stretchable display medium layer 200 to form an edge package, thereby improving the reliability of the shapable display device 100b.

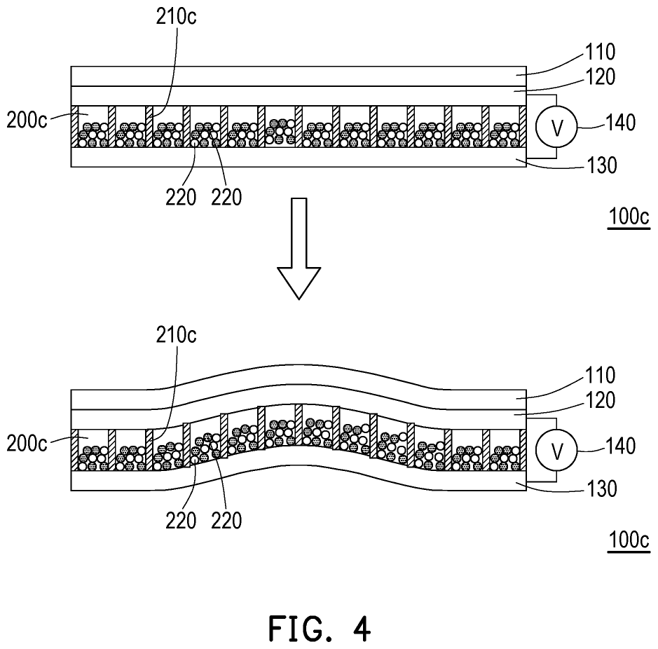

FIG. 4 is a schematic cross-sectional view of a shapable display device before and after shaping according to still another embodiment of the disclosure. Referring to FIG. 4, a shapable display device 100c of the embodiment is similar to the shapable display device 100 of FIG. 1, and the main differences between the two are as follows. In a stretchable display medium layer 200c of the display device 100c of the embodiment, the capsule structures 210 in FIG. 1 are respectively replaced by a plurality of microcup structures 210c. The microcup structures 210c are distributed in the stretchable display medium layer 200c, and the electrophoretic particles 220 are configured in the microcup structures 210c.

In other embodiments, the capsule structures 210 in FIG. 2 and FIG. 3 can also be changed into the microcup structures 210c to form two other shapable display devices.

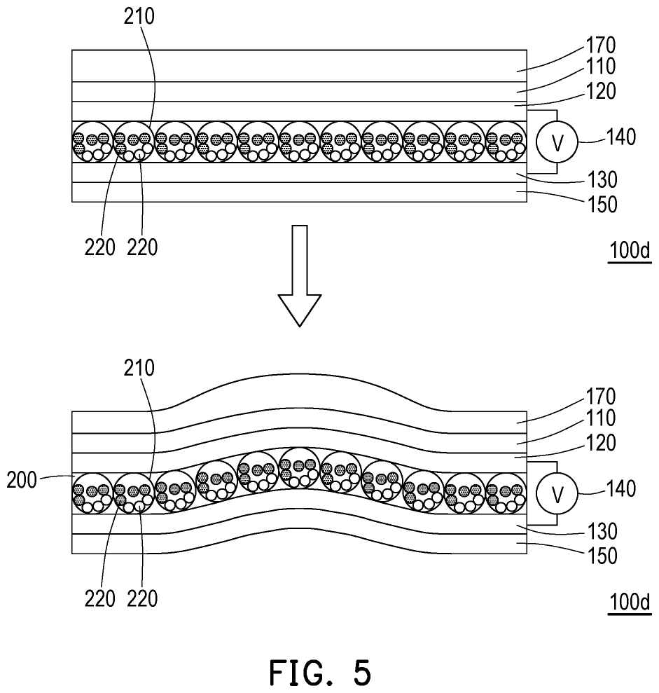

FIG. 5 is a schematic cross-sectional view of a shapable display device before and after shaping according to another embodiment of the disclosure. Referring to FIG. 5, a shapable display device 100d of the embodiment is similar to the shapable display device 100a of FIG. 2, and the main differences between the two are as follows. The shapable display device 100d of the embodiment further includes a decorative layer 170 configured on the first deformable substrate 110. The first deformable substrate 110 is located between the decorative layer 170 and the first stretchable electrode layer 120, and the decorative layer 170 is partially light-transmissive.

The decorative layer 170 may have various patterns to beautify the shapable display device 100d or to enhance the texture of the shapable display device 100d. In an embodiment, the decorative layer 170 can be formed by spraying pigment on the first deformable substrate 110, for example, by using a UV curing color spraying process. In addition, when the electrophoretic particles 220 are black electrophoretic particles and white electrophoretic particles, the decorative layer 170 can be sprayed with various colors, and the combination of the black electrophoretic particles and the white electrophoretic particles can form the grayscale effects of various colors as the position distribution of the voltage changes. However, in other embodiments, the electrophoretic particles 220 may also include colored electrophoretic particles, and a color picture can be provided through the display effects of the colored electrophoretic particles themselves.

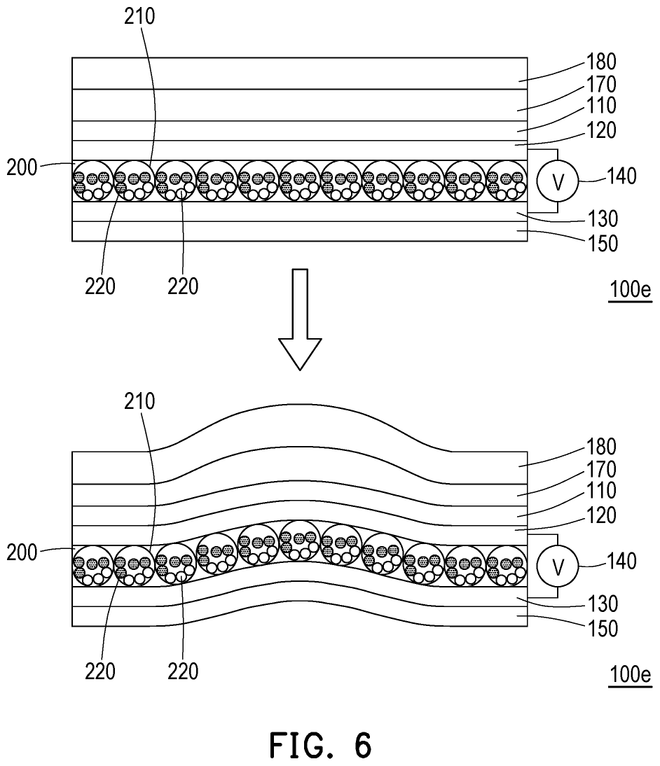

FIG. 6 is a schematic cross-sectional view of a shapable display device before and after shaping according to yet another embodiment of the disclosure. Referring to FIG. 6, a shapable display device 100e of the embodiment is similar to the shapable display device 100d of FIG. 5, and the main differences between the two are as follows. The shapable display device 100e of the embodiment further includes a textured film 180 disposed on the decorative layer 170. The textured film 180 can provide texture and a certain touch feeling on the surface of the shapable display device 100e, so as to enhance the texture of the shapable display device 100e. The surface of the textured film 180 can have geometric patterns or other forms of patterns, which can increase the touch feeling of the shapable display device 100e without making the user feel that the surface is similar to the surface of a general plastic product and has a cheap feeling. In addition, geometric patterns or other forms of patterns can be manufactured using processes such as spray printing and rolling.

In another embodiment, the decorative layer 170 in the shapable display device 100d of FIG. 5 can also be replaced by the textured film 180 to form another shapable display device, that is, such a kind of shapable display device only has the textured film 180 but does not have the decorative layer 170.

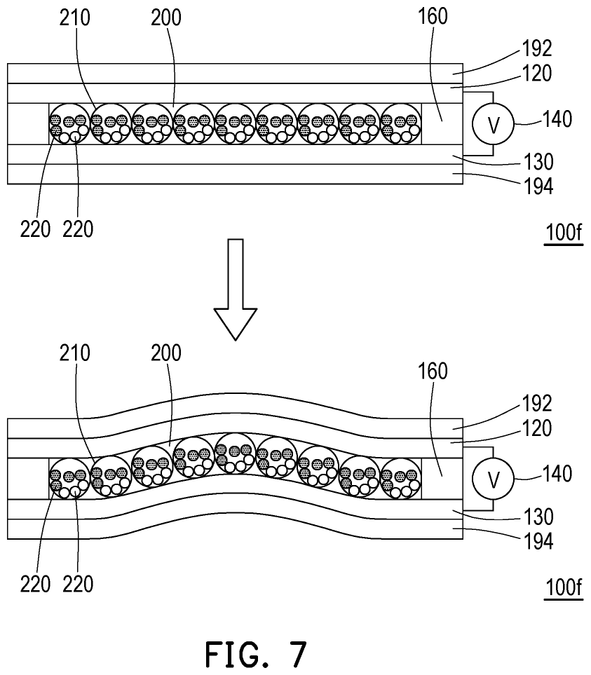

FIG. 7 is a schematic cross-sectional view of a shapable display device before and after shaping according to still another embodiment of the disclosure. Referring to FIG. 7, a shapable display device 100f of the embodiment is similar to the shapable display device 100b of FIG. 3, and the main differences between the two are as follows. The shapable display device 100f of the embodiment further includes a first water-blocking film 192 and a second water-blocking film 194, respectively configured on a side of the first stretchable electrode layer 120 facing away from the stretchable display medium layer 200 and a side of the second stretchable electrode layer 130 facing away from the stretchable display medium layer 200. In the embodiment, the shapable display device 100f does not have the first deformable substrate 110 and the second deformable substrate 150 of FIG. 3. Or, in an embodiment, from another perspective, the first water-blocking film 192 can also be regarded as a first deformable substrate that can block water. The first water-blocking film 192 and the second water-blocking film 194 can prevent water or moisture from entering the interior of the shapable display device 100f, thereby improving the reliability of the shapable display device 100f.

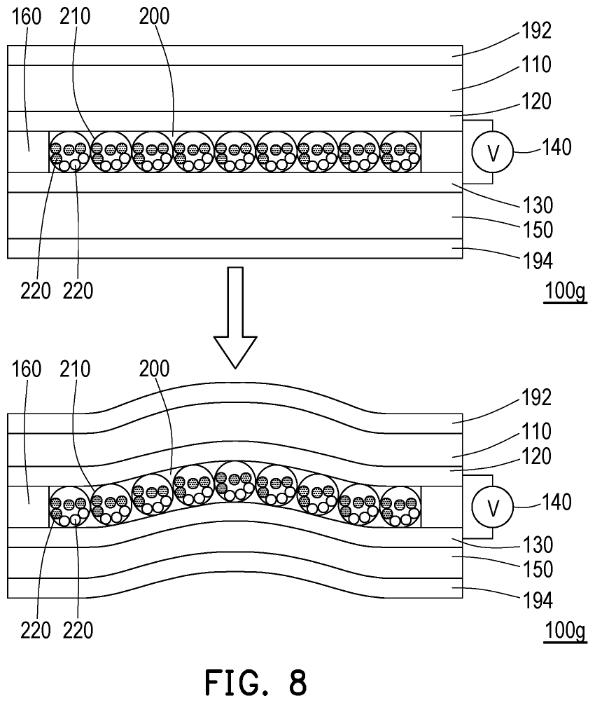

FIG. 8 is a schematic cross-sectional view of a shapable display device before and after shaping according to another embodiment of the disclosure. Referring to FIG. 8, a shapable display device 100g of the embodiment is similar to the shapable display device 100f of FIG. 7, and the main differences between the two are as follows. The shapable display device 100g of the embodiment includes the first deformable substrate 110 and the second deformable substrate 150. The first deformable substrate 110 is configured between the first stretchable electrode layer 120 and the first water-blocking film 192. The second deformable substrate 150 is disposed between the second stretchable electrode layer 130 and the second water-blocking film 194.

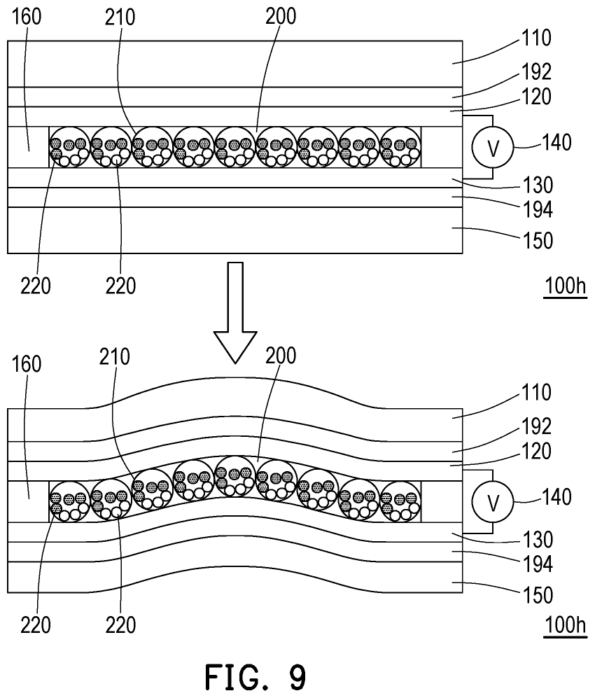

FIG. 9 is a schematic cross-sectional view of a shapable display device before and after shaping according to yet another embodiment of the disclosure. Referring to FIG. 9, a shapable display device 100h of the embodiment is similar to the shapable display device 100g of FIG. 8, and the main differences between the two are as follows. In the shapable display device 100h of the embodiment, the first water-blocking film 192 is configured between the first stretchable electrode layer 120 and the first deformable substrate 110, and the second water-blocking film 194 is configured between the second stretchable electrode layer 130 and the second deformable substrate 150.

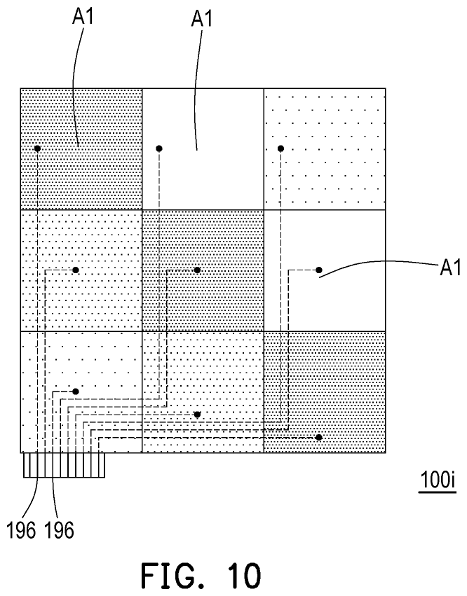

FIG. 10 is a schematic top view of a shapable display device formed by designing the shapable display device of FIG. 6 using segment code technology. Referring to FIG. 6 and FIG. 10, a shapable display device 100i of the embodiment has a plurality of blocks A1, and the blocks A1 can be arranged in an array. The structure of each block A1 may be the structure of the shapable display device 100e of FIG. 6. One of the first stretchable electrode layers 120 and the second stretchable electrode layers 130 of the blocks A1 may be connected together or electrically connected together, and the other one of the first stretchable electrode layers 120 and the second stretchable electrode layers 130 of the blocks A1 may be independently and electrically connected to a plurality of different pads 196 respectively. In this way, different blocks A1 can be independently controlled to have different display effects, so that the shapable display device 100i has variable display effects.

To sum up, in the shapable display device according to the embodiment of the disclosure, since the first deformable substrate, the first stretchable electrode layer, the stretchable display medium layer, and the second stretchable electrode layer are all deformable or stretchable, the display device can be configured on an object with a three-dimensional shape and bend along with the three-dimensional shape. In other words, the shapable display device of the embodiment of the disclosure can achieve a three-dimensional shaping effect.

What is claimed is:

1. A shapable display device, comprising:
a first deformable substrate;
a first stretchable electrode layer, configured on the first deformable substrate;
a stretchable display medium layer, configured on the first stretchable electrode layer; and
a second stretchable electrode layer, configured on the stretchable display medium layer, wherein the stretchable display medium layer is between the first stretchable electrode layer and the second stretchable electrode layer.

2. The shapable display device according to claim 1, further comprising a second deformable substrate configured on the second stretchable electrode layer.

3. The shapable display device according to claim 1, further comprising a package material configured around the stretchable display medium layer to form an edge package.

4. The shapable display device according to claim 1, wherein the stretchable display medium layer comprises a plurality of capsule structures and a plurality of electrophoretic particles, the capsule structures are distributed in the stretchable display medium layer, and the electrophoretic particles are configured in the capsule structures.

5. The shapable display device according to claim 1, wherein the stretchable display medium layer comprises a plurality of microcup structures and a plurality of electrophoretic particles, the microcup structures are distributed in the stretchable display medium layer, and the electrophoretic particles are configured in the microcup structures.

6. The shapable display device according to claim 1, further comprising a decorative layer configured on the first deformable substrate, wherein the first deformable substrate is located between the decorative layer and the first stretchable electrode layer, and the decorative layer is partially light-transmissive.

7. The shapable display device according to claim 6, further comprising a textured film configured on the decorative layer.

8. The shapable display device according to claim 1, further comprising a textured film configured on the first deformable substrate, wherein the first deformable substrate is located between the textured film and the first stretchable electrode layer.

9. The shapable display device according to claim 1, further comprising a first water-blocking film and a second water-blocking film respectively configured on a side of the first stretchable electrode layer facing away from the stretchable display medium layer and a side of the second stretchable electrode layer facing away from the stretchable display medium layer.

10. The shapable display device according to claim 9, wherein the first water-blocking film is configured between the first stretchable electrode layer and the first deformable substrate.

11. The shapable display device according to claim 9, wherein the first deformable substrate is configured between the first stretchable electrode layer and the first water-blocking film.

12. The shapable display device according to claim 9, further comprising a second deformable substrate, wherein the second water-blocking film is configured between the second stretchable electrode layer and the second deformable substrate.

13. The shapable display device according to claim 9, further comprising a second deformable substrate, wherein the second deformable substrate is configured between the second stretchable electrode layer and the second water-blocking film.

14. The shapable display device according to claim 1, wherein the first deformable substrate is a thermoplastic substrate.

15. The shapable display device according to claim 1, wherein a material of the first deformable substrate is amorphous polyethylene terephthalate (APET), and materials of the first stretchable electrode layer and the second stretchable electrode layer are poly(3,4-ethylenedioxythiophene) (PEDOT).

16. The shapable display device according to claim 15, wherein the stretchable display medium layer comprises colored electrophoretic particles.

17. The shapable display device according to claim 15, further comprising a second deformable substrate configured on the second stretchable electrode layer, wherein a material of the second deformable substrate is amorphous polyethylene terephthalate (APET).

18. The shapable display device according to claim 1, wherein the shapable display device is divided into a plurality of blocks, one of the first stretchable electrode layers and the second stretchable electrode layers of the blocks are connected together or electrically connected together, and the other one of the first stretchable electrode layers and the second stretchable electrode layers of the blocks are independently and electrically connected to a plurality of different pads respectively.
